(19) United States
(12) Patent Application Publication
(10) Pub. No.: US 2019/0326326 A1
(43) Pub. Date: Oct. 24, 2019

(54) DISPLAY APPARATUS AND METHOD OF MANUFACTURING THE SAME

(71) Applicant: Samsung Display Co., Ltd., Yongin-si (KR)

(72) Inventors: Jina SEO, Yongin-si (KR); Yunho LEE, Yongin-si (KR)

(21) Appl. No.: 16/253,412

(22) Filed: Jan. 22, 2019

(30) Foreign Application Priority Data
Apr. 19, 2018 (KR) 10-2018-0045740

(51) Int. Cl. H01L 27/12; H01L 51/52; H01L 27/32; G09G 3/3225

(52) U.S. Cl. CPC H01L 27/124; G09G 3/3225; H01L 27/3276; H01L 51/5203

(57) ABSTRACT

A display apparatus includes a substrate including a display area and a non-display area around the display area, a plurality of signal lines on the display area of the substrate, a plurality of pads on the non-display area of the substrate, the plurality of pads being connected to the plurality of signal lines, and a plurality of protrusions on the non-display area of the substrate, the plurality of protrusions being positioned among the plurality of pads.

### CROSS-REFERENCE TO RELATED APPLICATION

Korean Patent Application No. 10-2018-0045740, filed on Apr. 19, 2018, in the Korean Intellectual Property Office, and entitled: “Display Apparatus and Method of Manufacturing the Same,” is incorporated by reference herein in its entirety.

### BACKGROUND

### 1. Field

One or more embodiments relate to a display apparatus and a method of manufacturing the same.

### 2. Description of the Related Art

An electronic apparatus, e.g., a display apparatus, may include a plurality of circuit wirings and a plurality of electronic elements connected to the plurality of circuit wirings, and may operate by receiving an electrical signal. A conductive adhesive or a conductive film may be used to electrically connect the plurality of circuit wirings to the electronic elements.

### SUMMARY

According to one or more embodiments, a display apparatus may include a substrate including a display area and a non-display area around the display area, a plurality of pads located on the non-display area of the substrate and connected to signal lines of the display area, and protrusions located between the plurality of pads.

The display apparatus may further include an integrated circuit including a plurality of bumps connected to the plurality of pads.

The display apparatus may further include a conductive adhesive member configured to electrically connect the plurality of pads and the plurality of bumps.

The conductive adhesive member may include conductive particles.

The protrusions may have a height greater than a diameter of the conductive particles.

The protrusions may contact the conductive adhesive member.

The display apparatus may further include a plurality of fan-out lines configured to connect the signal lines to the plurality of pads.

The protrusions may include the same material as a material of one of a plurality of insulating layers of the display area.

The plurality of pads may include the same material as a material of one electrode of a thin-film transistor of the display area.

A width of the protrusions may be less than an interval between the plurality of pads.

The display apparatus may further include a thin-film transistor located on the display area, a first insulating layer covering the thin-film transistor, and a second insulating layer having an opening through which a part of a first electrode on the first insulating layer is exposed and covering an edge of the first electrode, wherein the protrusions include the same material as a material of the first insulating layer and the second insulating layer.

According to one or more embodiments, a method of manufacturing a display apparatus may include providing a substrate including a display area and a non-display area around the display area, forming a plurality of pads connected to signal lines of the display area on the non-display area of the substrate, and forming protrusions between the plurality of pads.

The method may further include connecting an integrated circuit including a plurality of bumps corresponding to the plurality of pads, to the plurality of pads.

The method may further include providing a conductive adhesive member between the plurality of pads and the integrated circuit.

The conductive adhesive member may include conductive particles.

The protrusions may have a height greater than a diameter of the conductive particles.

The protrusions may contact the conductive adhesive member.

A width of the protrusions may be less than an interval between the plurality of pads.

The protrusions may be formed at the same time as one of a plurality of insulating layers of the display area is formed.

The plurality of pads may be formed at the same time as one electrode of a thin-film transistor of the display area is formed.

### BRIEF DESCRIPTION OF THE DRAWINGS

Features will become apparent to those of skill in the art by describing in detail exemplary embodiments with reference to the attached drawings, in which:

FIG. 1 illustrates a conceptual view of a display apparatus according to an embodiment;

FIG. 2 illustrates a circuit diagram of a pixel according to an embodiment;

FIG. 3 illustrates a partial cross-sectional view along line I-I′ of FIG. 1;

FIG. 4 illustrates a plan view of an arrangement of protrusions of the display apparatus of FIG. 1;

FIG. 5 illustrates a schematic view of a potential short-circuit between pads according to an embodiment;

FIG. 6 illustrates a cross-sectional view of a display area and a non-display area of the display apparatus of FIG. 1; and

FIGS. 7 through 9 illustrate cross-sectional views of stages in a method of f manufacturing a display apparatus according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that although the terms “first”, “second”, etc. may be used herein to describe various elements, these elements should not be limited by these terms. These elements are only used to distinguish one element from another. As used herein, the singular forms “a”, “an”, and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

As used herein, the term “and/or” includes any and all combinations of one or more of the associated listed items. Expressions such as “at least one of,” when preceding a list of elements, modify the entire list of elements and do not modify the individual elements of the list.

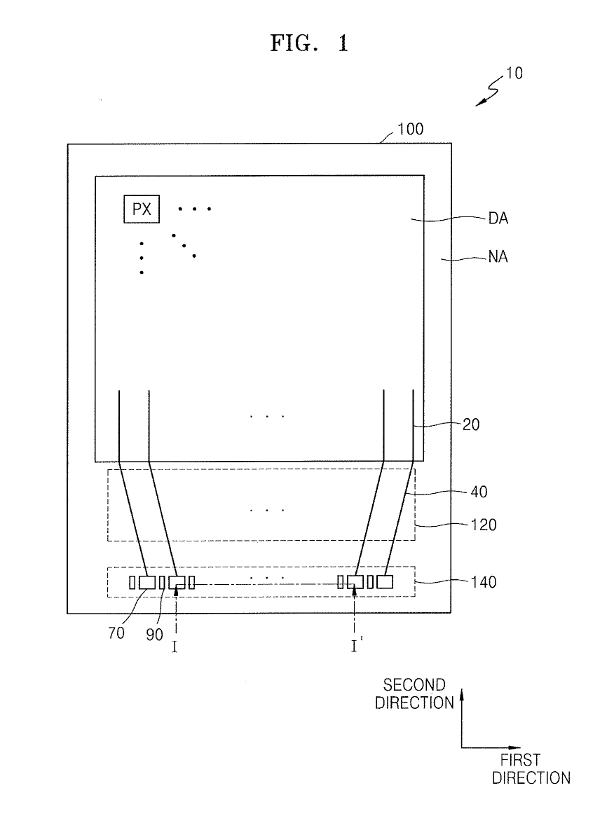

FIG. 1 is a conceptual view of a display apparatus 10 according to an embodiment.

Referring to FIG. 1, the display apparatus 10 may include a substrate 100, a plurality of pixels PX arranged on a display area DA of the substrate 100, and a mounting area 140 located on a non-display area NA of the substrate 100. The non-display area NA may be around, e.g., completely surround a perimeter of, the display area DA. For example, as illustrated in FIG. 1, the mounting area 140 may be defined at an edge of the substrate 100 to accommodate signal pads 70, and a fan-out portion 120 may be defined on the non-display area NA, i.e., between the display area DA and the mounting area 140, to accommodate wiring, e.g., a plurality of fan-out lines 40, connecting the display area DA to the mounting area 140.

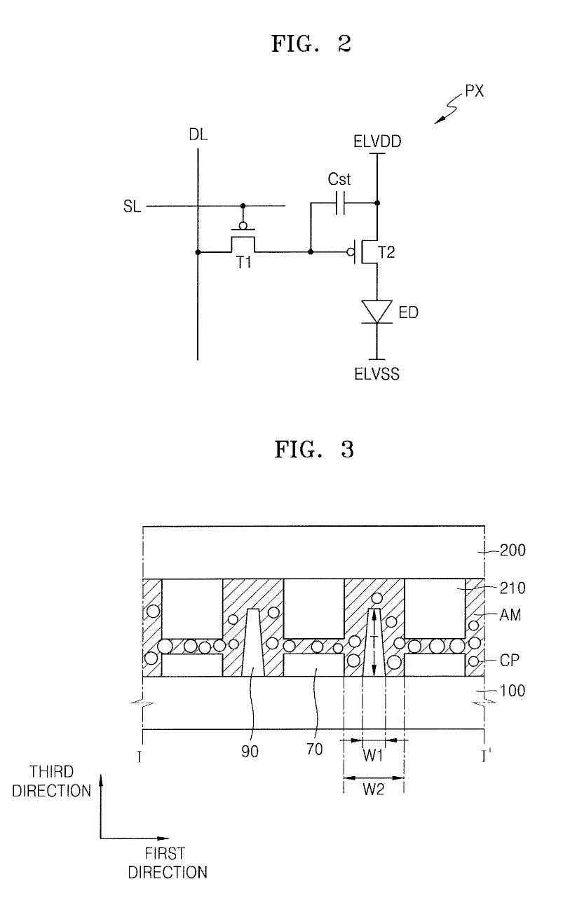

On the display area DA, each of the plurality of pixels PX is connected to a corresponding data line DL and a corresponding scan line SL (FIG. 2), respectively receives a scan signal and a data signal from the corresponding scan line SL and the corresponding data line DL, and emits light of a predetermined color. On the display area DA, a plurality of the scan lines SL may extend in a first direction or a second direction that intersects with the first direction, and a plurality of the data lines DL may extend in the second direction or the first direction, e.g., to intersect the plurality of scan lines SL.

As illustrated in FIG. 1, the signal pads 70 connected to the fan-out lines 40 of the fan-out portion 120 are formed on the mounting area 140. The signal pads 70 may be spaced apart from one another. e.g., along the first direction, on the mounting area 140. The fan-out lines 40 may be connected to a plurality of signal lines 20 located on the display area DA, e.g., the fan-out lines 40 may extend between the signal lines 20 and the signal pads 70 along the second direction to electrically connect therebetween. The fan-out lines 40 may extend from the signal lines 20 or may be electrically connected to the signal lines 20 through separate connection members. The signal lines 20 may include the scan lines SL and the data lines DL. The signal pads 70 may include gate pads connected to the scan lines SL and data pads connected to the data lines DL.

On the mounting area 140, a driving unit 200 (FIG. 3) may be mounted as an integrated circuit chip by using a chip-on-glass (COG) method. The driving unit 200, e.g., an integrated circuit 200, may include a scan driver for generating a scan signal and outputting the scan signal to the plurality of scan lines SL and/or a data driver for generating a data signal and outputting the data signal to the plurality of data lines DL. The driving unit 200 may further include contact pads (e.g., bumps, conductive balls, and conductive pins) that may be connected to the signal pads 70, e.g., the driving unit 200 may include bumps 210 extending downwardly from the driving unit 200 to electrically connect the driving unit 200 to the signal pads 70.

The signal pads 70 may include a transparent conductive film, e.g., indium tin oxide (ITO) or indium zinc oxide (IZO), or a metal or an alloy, e.g., aluminum or silver. However, the signal pads 70 are not limited to the above materials and may include any of various conductive materials having corrosion resistance.

Positions and number of lines for connecting elements in the display apparatus 10 and the signal pads 70, e.g., positions and number of the fan-out lines 40, are shown in FIG. 1 for convenience, and thus, the lines may be located at different positions. Although the signal pads 70 are arranged in one row in FIG. 1, embodiments are not limited thereto. For example, some signal pads may be arranged in a zigzag pattern.

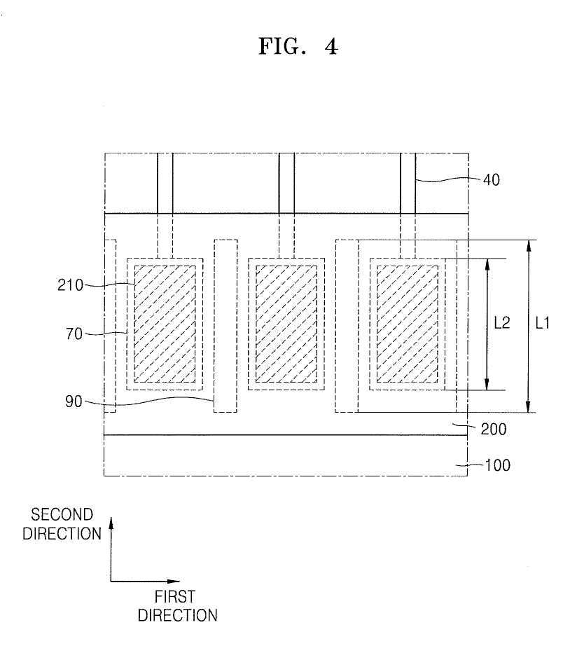

As further illustrated in FIG. 1, protrusions 90 may be located on the substrate 100. The protrusions 90 may be located between, e.g., among, the signal pads 70. For example, the protrusions 90 may be positioned on, e.g., along, the mounting area 140, e.g., one protrusion 90 may be between two signal pads 70 adjacent to each other along the first direction. The protrusions 90 may prevent a short-circuit between adjacent signal pads 70, e.g., prevent conductive particles from electrically connecting the signal pads 70 and the driving unit 200, thereby preventing or substantially minimizing vertical line defects caused by a short-circuit between channels, i.e., between signal lines, of the display area DA. The protrusions 90 will be described in more detail below with reference to FIGS. 3-4.

Examples of the display apparatus 10 may include various display apparatuses, e.g., an organic light-emitting display apparatus, a liquid-crystal display apparatus, and a field-emission display (FED) apparatus. While the following will be described assuming that the display apparatus 10 is an organic light-emitting display apparatus, embodiments are not limited thereto, i.e., the description may apply to other display apparatuses.

FIG. 2 is a circuit diagram of one pixel PX according to an embodiment.

Referring to FIG. 2, the pixel PX of the display apparatus 10 according to an embodiment may include a pixel circuit and a light-emitting device ED connected to the pixel circuit. The pixel circuit may include a first transistor T1, a second transistor T2, and a capacitor Cst.

The first transistor T1 includes a gate electrode connected to the scan line SL, a first electrode connected to the data line DL, and a second electrode. The second transistor T2 includes a gate electrode connected to the second electrode of the first transistor T1, a first electrode receiving a first power supply voltage ELVDD, and a second electrode connected to the light-emitting device ED. The capacitor Cst includes a first electrode connected to the second electrode of the first transistor T1 and the gate electrode of the second transistor T2, and a second electrode receiving the first power supply voltage ELVDD.

The light-emitting device ED may be connected to the pixel circuit through the second transistor T2. The light-emitting device ED may be an organic light-emitting diode (OLED). The organic light-emitting device ED includes a first electrode connected to the second electrode of the second transistor T2, a second electrode receiving a second power supply voltage ELVSS, and an emission layer between the first electrode and the second electrode. The first power supply voltage ELVDD may be higher than the second power supply voltage ELVSS.

Although one pixel PX includes two transistors and one capacitor in FIG. 2, the present disclosure is not limited thereto. For example, one pixel may include two or more transistors and one or more capacitors, and may be formed to have any of various structures by further forming a separate wiring or omitting an existing wiring. Although the pixel PX includes a P-type transistor in the above embodiment, embodiments are not limited thereto, e.g., a pixel of an embodiment may include an N-type transistor.

FIG. 3 is a partial cross-sectional view taken along line I-I′ of the display apparatus 10 of FIG. 1. FIG. 4 is a plan view for explaining an arrangement of the protrusions 90 of the display apparatus 10 of FIG. 1.

Referring to FIGS. 1, 3, and 4, the plurality of signal pads 70 may be located on the substrate 100 to be spaced apart from one another along the first direction. The plurality of signal pads 70 may be electrically connected to the driving unit 200 by a conductive adhesive member AM.

For example, as illustrated in FIG. 3, each of the plurality of signal pads 70 may be connected to a corresponding bump 210 of the driving unit 200, e.g., the signal pads 70 may be vertically aligned with corresponding ones of the bumps 210. The conductive adhesive member AM may be a conductive film including conductive particles CP. The conductive adhesive member AM may fill a space between the plurality of signal pads 70 and the driving unit 200, e.g., the conductive adhesive member AM may fill a space between the plurality of signal pads 70 and the corresponding ones of the bumps 210 of the driving unit 200 and a space along lateral surfaces of the signal pads 70 and the corresponding bumps 210.

The conductive adhesive member AM may include a polymer resin and the conductive particles CP dispersed in the polymer resin. The conductive particles CP may be conductive particles of a tin alloy formed by alloying tin with at least one of, e.g., silver, copper, bismuth, zinc, and indium. Alternatively, the conductive particles CP may be conductive particles of an indium alloy formed by alloying indium with at least one of, e.g., silver, copper, bismuth, zinc, and tin. The conductive particles CP may be conductive particles having a low melting temperature. For example, a melting temperature of the conductive particles CP including at least one of tin and indium may be equal to or greater than 60° C. and equal to or less than 200° C.

The conductive adhesive member AM may further include a thermoplastic resin. The thermoplastic resin may be a vinyl acetate resin, a styrene resin, an ethylene-vinyl acetate copolymer resin, or a styrene-butadiene copolymer resin. Alternatively, the thermoplastic resin may be a polyester resin.

As further illustrated in FIG. 3, the protrusions 90 may be located between, e.g., among, the plurality of signal pads 70. For example, as illustrated in FIG. 3, each protrusion 90 may be on the substrate 100 between two adjacent signal pads 70. For example, as illustrated in FIG. 3, the protrusions 90 and the signal pads 70 may be directly on the substrate 100, and the protrusions 90 may extend vertically along a third direction beyond the signal pads 70 to overlap both the signal pas 70 and the bumps 210 in the first direction. For example, the protrusions 90 may have a higher height than the signal pads 70 relative to the substrate 100, e.g., each protrusion 90 may be at least twice as high as the signal pad 70. For example, as illustrated in FIG. 3, the protrusions 90 may only partially overlap the bumps 210, so a space may be defined between top surfaces of the protrusions 90 and the driving unit 200 to accommodate the conductive adhesive member AM.

The protrusions 90 may guide the conductive particles CP of the conductive adhesive member AM to be located adjacent to the signal pads 70. As the conductive particles CP are located adjacent to the signal pads 70, a short-circuit between the signal pads 70 may be reduced.

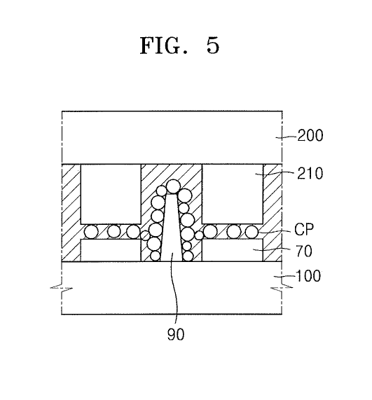

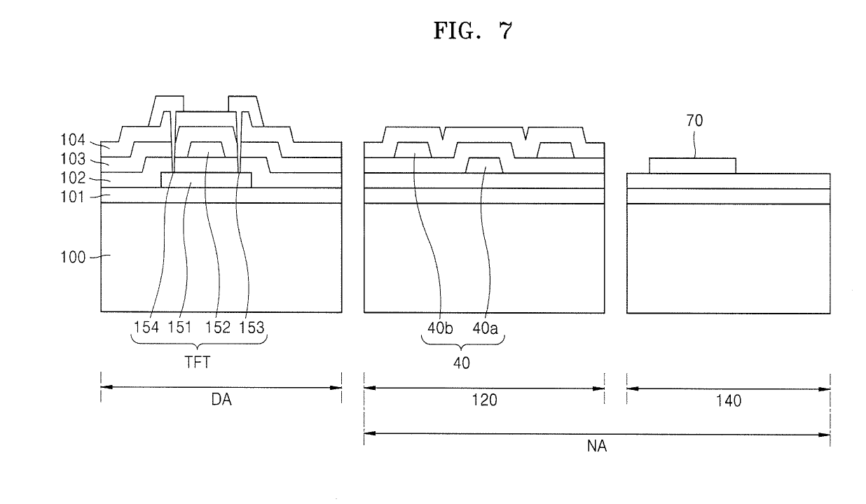

The protrusions 90 may be formed of an insulating material. The protrusions 90 may be formed of the same material as that of at least one of various insulating layers formed on the display area DA, as will be discussed in detail with reference to A FIGS. 5 and 7. The protrusions 90 may be formed at the same time as the plurality of insulating layers are formed on the display area DA. The protrusions 90 may be formed with a width thereof decreasing from the bottom to the top thereof.

In detail, as illustrated in FIG. 3, the protrusions 90 may have a height T along the third direction and a base width W1 along the first direction, so that the conductive particles CP are not located over the protrusions 90 and are located at lateral sides of the protrusions 90 to be close to the signal pads 70. For example, the height T, i.e., thickness, of the protrusions 90 may be equal to or greater than a diameter of the conductive particles CP. The height T of the protrusions 90 may be greater than a diameter of the conductive particles CP and may be less than an interval between the driving unit 200 and the substrate 100. The height T of the protrusions 90 may range from about 4 μm to about 10 μm. The base width W1 of the protrusions 90 is less than an interval W2 between the signal pads 70. The interval W2 between the signal pads 70 may range from about 10 μm to about 15 μm. The width W1 of the protrusions 90 may range from about 5 μm to about 10 μm.

As illustrated in FIG. 4, the protrusions 90 may be arranged along a length L2 of the signal pads 70 in the second direction. The length L1 of the protrusions 90 in the second direction may be the same as the length L2 of the signal pads 70. In another embodiment, the length L1 of the protrusions 90 may be greater than the length L2 of the signal pads 70.

The conductive particles CP included in the conductive adhesive member AM are irregularly arranged, without having a constant arrangement or interval. Accordingly, although a density of the conductive particles CP may be controlled, it is difficult to control an interval between the conductive particles CP. Also, the risk of a short-circuit between the signal pads 70 may be high when the density of the conductive particles CP is high, and driving may not be performed when the density of the conductive particles CP is low. Also, a short-circuit between the signal pads 70 may occur due to dielectric breakdown (DB) according to an operating voltage.

Therefore, according to example embodiments, the protrusions 90 are positioned between adjacent signal pads 70 to control the flow of the conductive particles CP while securing a minimum distance between the signal pads 70 for preventing DB. That is, the height of the protrusions 90 increases a flow path of the conductive particles CP between the signal pads 70, thereby minimizing a risk for short-circuit between the signal pads 70.

In detail, when there are no protrusions between adjacent signal pads, short-circuit may occur between the adjacent signal pads due to conductive particles of the conductive adhesive member. That is, when a distance between adjacent signal pads is small, a relatively small number of conductive particles may concentrate in a space between the adjacent signal pads and electrically connect therebetween, e.g., based on a shortest distance along the first direction between the adjacent signal pads.

In contrast, when the protrusions 90 according to an example embodiment are positioned between adjacent signal pads 70 and extend substantially above the adjacent signal pads 70, the number of conductive particles CP required to electrically connect the adjacent signal pads 70 over the height of the protrusions 90 is substantially increased. Accordingly, a potential for short-circuit between the adjacent signal pads 70 may be substantially reduced. That is, since the protrusions 90 according to an embodiment increase a path through which the conductive particles CP flow between the signal pads 70 (e.g., the path of the conductive particles CP over the protrusion 90 in FIG. 5 as opposed to a merely straight line path between the two adjacent pads 70 along the first direction), the risk of short-circuit between adjacent signal pads 70 may be reduced even when the number of conductive particles CP increases.

According to an embodiment, it is not necessary to change a size of the conductive particles CP according to a mode change by changing a height and/or a length of the protrusions 90 according to a model of the display apparatus 10.

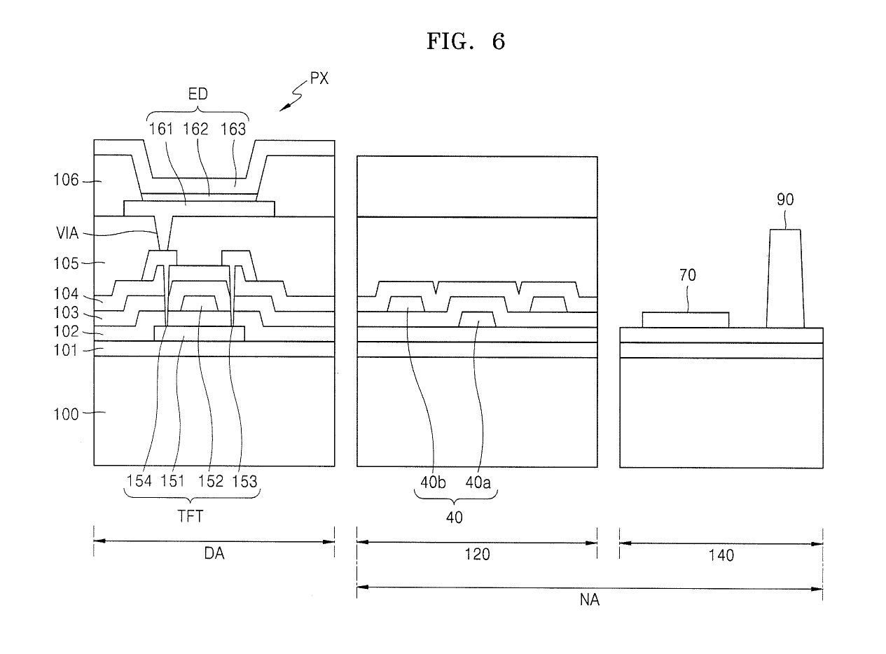

FIG. 6 is a cross-sectional view illustrating parts of the display area DA and the non-display area NA of the display apparatus 10 of FIG. 1.

Referring to FIG. 6, the display apparatus 10 according to an embodiment may include the pixels PX located on the display area DA, and the fan-out lines 40, the signal pads 70, and the protrusions 90 located on the non-display area NA.

The pixel circuit including a thin-film transistor TFT and the light-emitting device ED connected to the thin-film transistor TFT may be provided on the display area DA of the substrate 100. The thin-film transistor TFT may be the first transistor T1 or the second transistor T2 of FIG. 2. Although the thin-film transistor TFT of FIG. 6 is the first transistor T1, the second transistor T2 may be formed to have the same structure.

The thin-film transistor TFT may include an active layer 151, a gate electrode 152, a source electrode 153, and a drain electrode 154. A first insulating layer 102 may be located between the active layer 151 and the gate electrode 152. A second insulating layer 103 and a third insulating layer 104 may be located between the gate electrode 152, and the source electrode 153 and the drain electrode 154. Each of the source electrode 153 and the drain electrode 154 may have a single or multi-layer structure formed of a conductive material having high conductivity. For example, the source electrode 153 and the drain electrode 154 may include the same material as that of the gate electrode 152. The source electrode 153 and the drain electrode 154 may be respectively connected to a source region and a drain region of the active layer 151 through contact holes formed in the first insulating layer 102, the second insulating layer 103, and the third insulating layer 104.

The light-emitting device ED may be connected to the thin-film transistor TFT with a fourth insulating layer 105 therebetween. The light-emitting device ED may include a first electrode 161, a second electrode 163 facing the first electrode 161, and an intermediate layer 162 located between the first electrode 161 and the second electrode 163.

The first electrode 161 may be electrically connected to the source electrode 153 or the drain electrode 154 (the drain electrode 154 in FIG. 6) of the thin-film transistor TFT through a via hole VIA formed in the fourth insulating layer 105. The first electrode 161 may be a reflective film including a reflective conductive material, e.g., silver (Ag), magnesium (Mg), aluminum (Al), platinum (Pt), lead (Pb), gold (Au), nickel (Ni), neodymium (Nd), iridium (Ir), chromium (Cr), or a compound thereof. In an embodiment, the first electrode 161 may be a transparent conductive film including at least one transparent conductive oxide, e.g., indium tin oxide (ITO), indium zinc oxide (IZO), zinc oxide (ZnO), indium oxide (In₂O₃), indium gallium oxide (IGO), and aluminum zinc oxide (AZO). In an embodiment, the first electrode 161 may have a structure in which the reflective film and the transparent conductive film are stacked.

The second electrode 163 may include any of various conductive materials. For example, the second electrode 163 may include a transflective film including at least one of, e.g., lithium (Li), calcium (Ca), lithium fluoride (LiF), aluminum (Al), magnesium (Mg), and silver (Ag) or may include a transparent metal oxide, e.g., ITO, IZO, or ZnO, and may be formed to have a single or multi-layer structure.

The plurality of fan-out lines 40 may be formed on the fan-out portion 120 of the non-display area NA. The fan-out lines 40 may include first fan-out lines 40a formed between the first insulating layer 102 and the second insulating layer 103 and second fan-out lines 40b formed between the second insulating layer 103 and the third insulating layer 104. The first fan-out lines 40a and the second fan-out lines 40b may be formed of the same material or different materials. For example, the first fan-out lines 40a and the second fan-out lines 40b may be formed of the same material as that of the gate electrode 152 of the thin-film transistor TFT. Since a distance (interval) between adjacent fan-out lines located on different layers may be reduced by locating the first fan-out lines 40a and the second fan-out lines 40b on different layers with the second insulating layer 103 therebetween, a short-circuit between the fan-out lines 40 may be prevented while more fan-out lines 40 are formed on the same area. In another embodiment, the fan-out lines 40 may be formed on the same layer. The plurality of fan-out lines 40 may be covered by the second insulating layer 103, the third insulating layer 104, the fourth insulating layer 105, and a fifth insulating layer 106.

The plurality of signal pads 70 and the protrusions 90 located between the signal pads 70 may be formed on the mounting area 140 of the non-display area NA. The signal pads 70 may be formed on the first insulating layer 102. The signal pads 70 may be formed of the same material as that of one electrode of the thin-film transistor TFT. Although the signal pads 70 are formed of the same material as that of the gate electrode 152 in FIG. 6, in another embodiment, the signal pads 70 may be formed of the same material as that of the source electrode 153 and the drain electrode 154 on the third insulating layer 104.

The protrusions 90 may be formed between the signal pads 70. The protrusions 90 may be formed of the same material as that of the fourth insulating layer 105 and/or the fifth insulating layer 106.

FIGS. 7 through 9 are cross-sectional views of stages in a process of manufacturing the display apparatus 10 according to an embodiment.

Referring to FIG. 7, the pixel circuit of the pixels PX may be formed on the display area DA of the substrate 100, the fan-out lines 40 may be formed on the fan-out portion 120 of the non-display area NA, and the signal pads 70 may be formed on the mounting area 140. A buffer layer 101 may be formed on the substrate 100.

The substrate 100 may be formed of various materials, e.g., glass, metal, or plastic. According to an embodiment, the substrate 100 may be a flexible substrate formed of a flexible material. The flexible substrate formed of the flexible material refers to a substrate that may be easily curved, bent, folded, or rolled. The substrate formed of the flexible material may be formed of ultra-thin glass, metal, or plastic.

The buffer layer 101 may prevent penetration of impurity elements through the substrate 100 and may planarize a surface, and may have a single or multi-layer structure formed of an inorganic material, e.g., silicon nitride (SiNₓ) and/or silicon oxide (SiOₓ). The buffer layer 101 may be omitted.

After a semiconductor layer is formed on the buffer layer 101, the active layer 151 of the thin-film transistor TFT may be formed by patterning the semiconductor layer. The semiconductor layer may include any of various materials. For example, the semiconductor layer may include an inorganic semiconductor material, e.g., amorphous silicon or crystalline silicon. Alternatively, the semiconductor layer may include an oxide semiconductor or an organic semiconductor material.

The first insulating layer 102 that covers the active layer 151 may be formed on the substrate 100. The first insulating layer 102 may be an inorganic insulating film. The first insulating layer 102 may be formed to have a single or multi-layer structure including at least one insulating film of, e.g., silicon oxide (SIO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zirconium oxide (ZrO₂), BST, and PZT.

The gate electrode 152, the first fan-out lines 40a, and the signal pads 70 may be formed on the first insulating layer 102. The gate electrode 152 may be formed of any of various conductive materials. For example, the gate electrode 152 may have a single or multi-layer structure formed of at least one from among Al, Pt, palladium (Pd), Ag, Mg, Au, Ni, Nd, Ir, Cr, Li, calcium (Ca), molybdenum (Mo), titanium (Ti), tungsten (W), and copper (Cu). The gate electrode 152 may overlap at least a part of the active layer 151.

The first fan-out lines 40a and the signal pads 70 may be formed of the same material as that of the gate electrode 152 of the thin-film transistor TFT.

In an embodiment, the active layer 151 may be doped with B or P ion impurities by using the gate electrode 152 as a mask. Accordingly, the active layer 151 may include a source region and a drain region doped with ion impurities, and a channel region located between the source region and the drain region.

The second insulating layer 103 that covers the gate electrode 152, the first fan-out lines 40a, and the signal pads 70 may be formed on the substrate 100. The second insulating layer 103 may be an inorganic insulating film. The second insulating layer 103 may have a single or multi-layer structure including at least one insulating film among SiO₂, SiNₓ, SiON, Al₂O₃, TiO₂, Ta₂O₅, HfO₂, ZrO₂, BST, and PZT. In another embodiment, the second insulating layer 103 may be an organic insulating film.

The second fan-out lines 40b may be formed on the second insulating layer 103. The second fan-out lines 40b may be formed of the same material as that of the gate electrode 152 of the thin-film transistor TFT.

The third insulating layer 104 that covers the second insulating layer 103 and the second fan-out lines 40b may be formed on the substrate 100. The third insulating layer 104 may have a single or multi-layer structure formed of an inorganic material. For example, the third insulating layer 104 may include SiO₂, SiNₓ, SiON, Al₂O₃, TiO₂, Ta₂O₅, HfO₂, and/or ZrO₂. In another embodiment, the third insulating layer 104 may include an organic material.

Contact holes through which parts of the source region and the drain region of the active layer 151 are exposed may be formed in the third insulating layer 104 by patterning the third insulating layer 104 along with the first insulating layer 102 and the second insulating layer 103. In this case, the first insulating layer 102, the second insulating layer 103, and the third insulating layer 104 on the mounting area 140 may be patterned and removed.

The source electrode 153 and the drain electrode 154 may be formed on the third insulating layer 104. The source electrode 153 and the drain electrode 154 may be formed of the same material as that of the gate electrode 152. The source electrode 153 and the drain electrode 154 may respectively contact the source region and the drain region of the active layer 151.

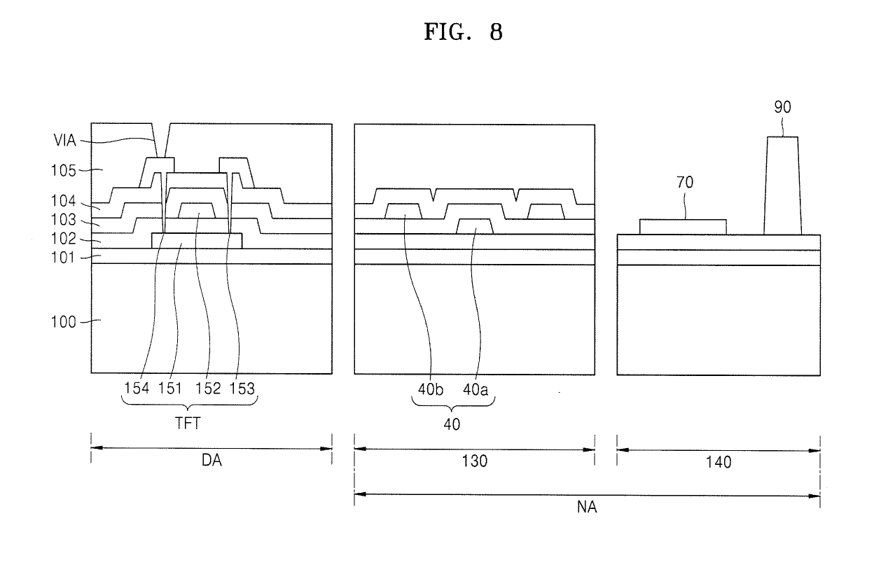

Referring to FIG. 8, the fourth insulating layer 105 that completely covers the thin-film transistor TFT may be formed on the substrate 100. The fourth insulating layer 105 may have a single or multi-layer structure formed of an organic material. The fourth insulating layer 105 may include a general-purpose polymer (e.g., polymethyl methacrylate (PMMA) or polystyrene (PS)), a phenol group-containing polymer derivative, an acrylic polymer, an imide-based polymer, an arylether-based polymer, an amide-based polymer, a fluorinated polymer, a p-xylene-based polymer, a vinyl alcohol-based polymer, and a blend thereof For example, the fourth insulating layer 105 may include polyimide, polyamide, or acrylic resin.

The via hole VIA through which a part of the source electrode 153 or the drain electrode 154 of the thin-film transistor TFT is exposed may be formed in the fourth insulating layer 105 by patterning the fourth insulating layer 105. For example, the protrusions 90 of the mounting area 140 may be formed by patterning the fourth insulating layer 105. In another example, the protrusions 90 may be formed by patterning the fifth insulating layer 106. In yet another example, the protrusions 90 may be formed to have a two-layer structure by patterning the fourth insulating layer 105 and the fifth insulating layer 106.

For example, in an embodiment, after the fourth insulating layer 105 is stacked on the substrate 100, the protrusions 90 of the non-display area NA and the via hole VIA of the display area DA may be formed by performing photolithography. In another embodiment, after the fifth insulating layer 106 is stacked on the substrate 100, the protrusions 90 of the non-display area NA and an opening through which the first electrode 161 of the display area DA is exposed may be formed by performing photolithography. In another embodiment, after the fourth insulating layer 105 is stacked on the substrate 100, a lower layer of the protrusions 90 of the non-display area NA and the via hole VIA of the display area DA may be formed by performing photolithography, and after the fifth insulating layer 106 is stacked on the substrate 100, an upper layer of the protrusions 90 of the non-display area NA and an opening through which the first electrode 161 of the display area DA is exposed may be formed by performing photolithography.

According to an embodiment, an additional process for forming the protrusions 90 is not required as the protrusions 90 are formed by changing a mask design for patterning an insulating layer.

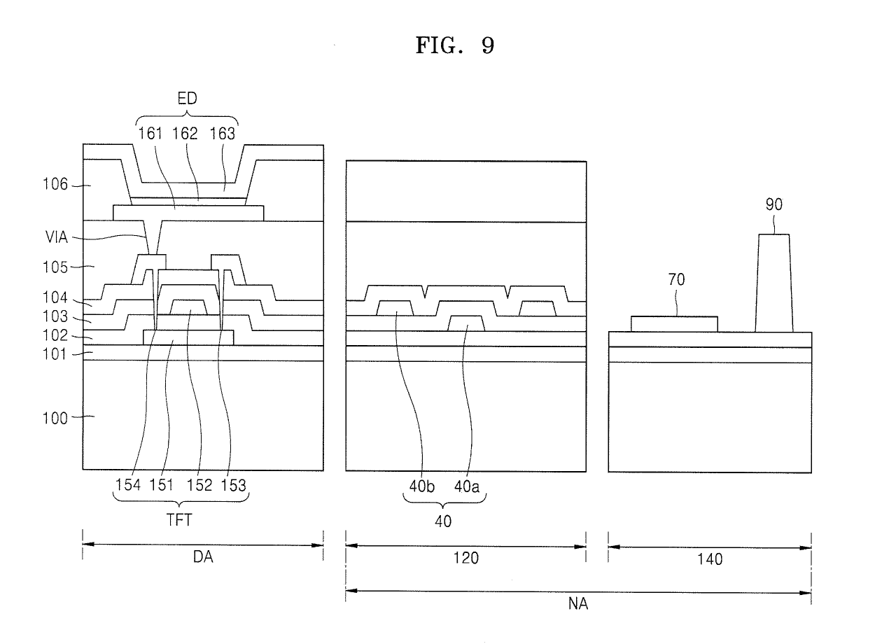

Referring to FIG. 9, the light-emitting device ED may be formed on the fourth insulating layer 105.

The first electrode 161 of the light-emitting device ED may be formed on the fourth insulating layer 105, and the first electrode 161 may be electrically connected to the source electrode 153 or the drain electrode 154 of the thin-film transistor TFT exposed through the via hole VIA formed in the fourth insulating layer 105. The fifth insulating layer 106 having an opening through which a part of the first electrode 161 is exposed may be formed on the first electrode 161 to cover an edge of the first electrode 161. The fifth insulating layer 106 may have a single or multi-layer structure formed of an organic material, like the fourth insulating layer 105.

The intermediate layer 162 including an emission layer may be formed on the first electrode 161 exposed by the fifth insulating layer 106. The emission layer may include a low molecular weight organic material or a high molecular weight organic material. The light-emitting device ED may emit red, green, and blue light according to a type of the emission layer. However, the present disclosure is not limited thereto, and a plurality of organic emission layers may be included in one light-emitting device ED. For example, a plurality of organic emission layers that emit red, green, and blue light may be vertically stacked or combined to emit white light. In this case, a color conversion layer or a color filter for converting white light into a predetermined color may be further provided. The red, green, and blue colors are examples, and a combination of colors for emitting white light is not limited thereto.

The intermediate layer 162 may include at least one functional layer from among a hole injection layer, a hole transport layer, an electron transport layer, and an electron injection layer between the first electrode 161 and the emission layer and/or between the emission layer and the second electrode 163. According to an embodiment, the intermediate layer 162 may further include various functional layers other than the above layers.

Although the intermediate layer 162 is patterned to correspond only to the first electrode 161 in FIG. 9 for convenience, the intermediate layer 162 may be integrally formed with the intermediate layer 162 of an adjacent pixel. Also, various modifications may be made, e.g., some layers of the intermediate layers 162 may be formed according to pixels, and other layers may be integrally formed with the intermediate layers 162 of an adjacent pixel. The second electrode 163 on the intermediate layer 162 may be formed over the entire display area DA of the substrate 100.

By way of summation and review, one or more embodiments may provide a display apparatus for preventing vertical line defects on a screen by preventing a short-circuit between spider wirings. That is, according to embodiments, protrusions are positioned between adjacent signal pads to increase a flow path of conductive particles between the adjacent signal pads, thereby minimizing a risk for a short-circuit between the adjacent signal pads.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display apparatus, comprising:
a substrate including a display area and a non-display area around the display area;
a plurality of signal lines on the display area of the substrate;
a plurality of pads on the non-display area of the substrate, the plurality of pads being connected to the plurality of signal lines; and
a plurality of protrusions on the non-display area of the substrate, the plurality of protrusions being positioned among the plurality of pads.

2. The display apparatus as claimed in claim 1, further comprising an integrated circuit including a plurality of bumps connected to the plurality of pads, respectively.

3. The display apparatus as claimed in claim 2, further comprising a conductive adhesive member electrically connecting the plurality of pads and the plurality of bumps.

4. The display apparatus as claimed in claim 3, wherein the conductive adhesive member includes conductive particles.

5. The display apparatus as claimed in claim 4, wherein the plurality of protrusions have a height greater than a diameter of the conductive particles.

6. The display apparatus as claimed in claim 3, wherein the plurality of protrusions contact the conductive adhesive member.

7. The display apparatus as claimed in claim 1, further comprising a plurality of fan-out lines to connect the plurality of signal lines to the plurality of pads.

8. The display apparatus as claimed in claim 1, further comprising at least one insulating layer in the display area, the plurality of protrusions including a same insulating material as a material of the at least one insulating layer in the display area.

9. The display apparatus as claimed in claim 1, further comprising a thin-film transistor in the display area, the plurality of pads including a same material as a material of one electrode of the thin-film transistor.

10. The display apparatus as claimed in claim 1, wherein a base width of one protrusion of the plurality of protrusions is less than an interval between two adjacent pads of the plurality of pads.

11. The display apparatus as claimed in claim 1, further comprising:
a thin-film transistor on the display area;
a first insulating layer covering the thin-film transistor;
a first electrode on the first insulating layer; and
a second insulating layer on the first insulating layer and covering an edge of the first electrode, the second insulating layer having an opening exposing a part of the first electrode,
wherein the plurality of protrusions includes a same material as a material of the first insulating layer and the second insulating layer.

12. The display apparatus as claimed in claim 1, wherein each protrusion of the plurality of protrusions is between two adjacent pads of the plurality of pads, a topmost surface of the protrusion being higher than topmost surfaces of the two adjacent pads relatively to the substrate.

13. A method of manufacturing a display apparatus, the method comprising:
providing a substrate including a display area and a non-display area around the display area;
forming a plurality of signal lines on the display area of the substrate;
forming a plurality of pads on the non-display area of the substrate, such that the plurality of pads is connected to the plurality of signal lines; and
forming a plurality of protrusions on the non-display area of the substrate, such that the plurality of protrusions is positioned among the plurality of pads.

14. The method as claimed in claim 13, further comprising connecting an integrated circuit having a plurality of bumps to corresponding ones of the plurality of pads, respectively.

15. The method as claimed in claim 14, further comprising providing a conductive adhesive member between the plurality of pads and the integrated circuit.

16. The method as claimed in claim 15, wherein the conductive adhesive member includes conductive particles.

17. The method as claimed in claim 16, wherein the plurality of protrusions has a height greater than a diameter of the conductive particles.

18. The method as claimed in claim 15, wherein the plurality of protrusions contact the conductive adhesive member.

19. The method as claimed in claim 13, wherein a base width of the plurality of protrusions is less than an interval between adjacent pads of the plurality of pads.

20. The method as claimed in claim 12, further comprising:
forming at least one insulating layer in the display area, the plurality of protrusions being formed at a same time as the at least one insulating layer; and
forming a thin-film transistor on the display area, the plurality of pads being formed at a same time as at least one electrode of the thin-film transistor.
